(19) United States
(12) Patent Application Publication
(10) Pub. No.: US 2009/0029561 A1
(43) Pub. Date: Jan. 29, 2009

(54) Semiconductor processing apparatus

(75) Inventors: Masanao Fukuda, Toyama-shi (JP); Kazuhiro Morimitsu, Toyama-shi (JP); Takafumi Sasaki, Toyama-shi (JP)

Correspondence Address: OLIFF & BERRIDGE, PLC, P.O. BOX 320850, ALEXANDRIA, VA, 22320-4850, US

(73) Assignee: HITACHI KOKUSAI ELECTRIC INC., Tokyo (JP)

(21) Appl. No.: 12/219,131

(22) Filed: Jul. 16, 2008

(30) Foreign Application Priority Data
Jul. 26, 2007 (JP) 2007-195055

(51) Int. Cl. H01L 21/283; C23C 16/00

(52) U.S. Cl. 438/758; 118/728; 257/E21.159

(57) ABSTRACT

There is provided a semiconductor processing apparatus comprising a processing tube for housing a substrate support member that supports a plurality of substrates stacked at a prescribed pitch in a vertical direction; a gas supply part that extends in a direction in which the substrates are stacked in the processing tube and that has a plurality of gas supply openings; an exhaust part that opens onto the processing tube; a gas rectifying plate that is disposed in a space between a penumbra of the substrates supported on the substrate support member and an inner wall of the processing tube, and that extends from the gas supply part in a circumferential direction of the processing tube and in the direction in which the substrates are stacked; and a gas flow regulating part disposed in a space in the processing tube that is above a top-most gas supply opening and a top-most substrate and in a space in the processing tube that is below a bottom-most substrate and a bottom-most gas supply opening. A thin film formed on the substrate can be made more uniform.

### BACKGROUND OF THE INVENTION

1. Field of the Invention

The present invention relates to a semiconductor processing apparatus whereby substrates are processed by supplying gas to the interior of a processing tube.

2. Description of the Related Art

In the past, a semiconductor processing step involving the formation of a thin film on a substrate has been carried out as one of the steps of producing semiconductor devices such as DRAMs. The semiconductor processing apparatus used for carrying out this type of semiconductor processing step has been equipped with a processing tube for housing a substrate support member that supports a plurality of substrates stacked at a prescribed pitch in the vertical direction, a gas supply part that supplies gas to the interior of the processing tube, and an exhaust part that opens into the processing tube. A substrate support member that supports a plurality of substrates is loaded to an inside of the processing tube, and gas is supplied into the processing tube using a gas supply part while exhausting the interior of the processing tube using the exhaust part, thereby forming thin films on the substrates as gas passes between each of the substrates.

### [Patent Document 1] Japanese Patent Laid Open Publication No.

### [Patent Document 2] Japanese Patent Laid Open Publication No.

### [Patent Document 3] Japanese Patent Laid Open Publication No.

The film thickness of the thin film formed in the above semiconductor processing step is preferably uniform across the entire surface of the substrate. However, when a plurality of substrates are loaded into the processing tube and the semiconductor processing step is carried out, there are cases where the film thickness of the resulting thin film is thicker in the penumbra of the substrates and thinner in the center parts of the substrates.

### SUMMARY OF THE INVENTION

An object of the present invention is to provide a semiconductor processing apparatus that can improve uniformity in the thickness of the thin film that is formed on a substrate.

A first aspect of the present invention provides a semiconductor processing apparatus comprising: a processing tube for housing a substrate support member that supports a plurality of substrates stacked at a prescribed pitch in a vertical direction; a gas supply part that extends in a direction in which the substrates are stacked in the processing tube and that has a plurality of gas supply openings; an exhaust part that opens onto the processing tube; a gas rectifying plate that is disposed in a space between a penumbra of the substrates supported on the substrate support member and an inner wall of the processing tube, and that extends from the gas supply part in a circumferential direction of the processing tube and in the direction in which the substrates are stacked; and a gas flow regulating part disposed in a space in the processing tube that is above a top-most gas supply opening and a top-most substrate and in a space in the processing tube that is below a bottom-most substrate and a bottom-most gas supply opening.

### BRIEF DESCRIPTION OF THE DRAWINGS

FIG. 1 is a schematic vertical sectional view of the semiconductor processing apparatus according to an embodiment of the present invention;

FIG. 2 is a schematic view of the cross-section A-A of the heat processing furnace equipped with the semiconductor processing apparatus according to an embodiment of the present invention;

FIG. 3 is a graph showing the relationship between the wafer height position and the flow rate of gas passing through the centers of the wafers;

FIG. 4 is an enlarged view of the configuration of region B of the heat processing furnace equipped with the semiconductor processing apparatus according to an embodiment of the present invention;

FIG. 5 is an enlarged view of the configuration of region C of the heat processing furnace equipped with the semiconductor processing apparatus according to an embodiment of the present invention;

FIG. 6 shows the structure of the heat processing furnace equipped with the semiconductor processing apparatus according to another embodiment of the present invention, where FIG. 6A is a vertical sectional view of the heat processing furnace, FIG. 6B is a partially enlarged view of region E, and FIG. 6C is a partially enlarged view of region F;

FIG. 7 is a vertical sectional view of the configuration of the heat processing furnace equipped with the semiconductor processing apparatus according to an embodiment of the present invention as viewed from direction D in FIG. 2;

FIG. 8 shows the structure of the heat processing furnace equipped with the semiconductor processing apparatus according to another embodiment of the present invention, where FIG. 8A shows the scheme whereby the gas rectifying plate is securely welded in one or more locations on the inner wall of the processing tube, FIG. 8B is a schematic view of the cross-section I-I of the heat processing furnace, FIG. 8C is an enlarged view of the configuration of region G, and FIG. 8D is an enlarged view of the configuration of region H;

FIG. 9 is a schematic view showing the results of simulation of gas flow in the heat processing furnace according to an embodiment of the present invention;

FIG. 10 is a schematic view showing the results of simulation of gas flow in a conventional heat processing furnace;

FIG. 11 is a perspective view showing the structure of the heat processing furnace equipped with the semiconductor processing apparatus according to an embodiment of the present invention;

FIG. 12 is a perspective view showing the structure of the heat processing furnace equipped with a conventional semiconductor processing apparatus;

FIG. 13 is a schematic horizontal sectional view of the heat processing furnace according to another embodiment of the present invention;

FIG. 14 is a schematic horizontal sectional view of the heat processing furnace according to another embodiment of the present invention;

FIG. 15 is a schematic vertical sectional view of the heat processing furnace equipped with a conventional semiconductor processing apparatus;

FIG. 16 is a schematic view of the cross-section J-J of the heat processing furnace equipped with a conventional semiconductor processing apparatus; and

FIG. 17 is a view of the overall configuration of the semiconductor processing apparatus according to an embodiment of the present invention.

### DESCRIPTION OF THE PREFERRED EMBODIMENTS

As described above, in conventional semiconductor processing apparatuses, there are cases where the film thickness of the thin film formed on a substrate has poor uniformity when substrate treatment is carried out by introducing multiple substrates into a processing tube.

The inventors of the present invention carried out painstaking investigations into the causes of uniformity loss. As a result, the inventors realized that the distribution of the flow resistance inside the processing tube is related to the loss of film thickness uniformity. Specifically, although it is necessary to use a fine stacking pitch for the substrates in order to load a large number of substrates into the processing tube, it was realized that the supply amount of gas in the vicinity of the center of the substrates is decreased, from a relative standpoint, because it is difficult for gas to pass between the substrates due to the increase in gas flow resistance in the region in which the substrates are carried resulting from the decrease in substrate stacking pitch. The inventors of the present invention thus realized that the flow resistance of gas in the processing tube can be adjusted appropriately and that the uniformity of the film thicknesses of the thin films formed on the substrates can be improved by providing the gas rectifying plate or gas flow regulating part described below in prescribed locations in the processing tube. The present invention is based on the knowledge obtained by the inventors of the present invention.

### (1) Configuration of the Semiconductor Processing Apparatus.

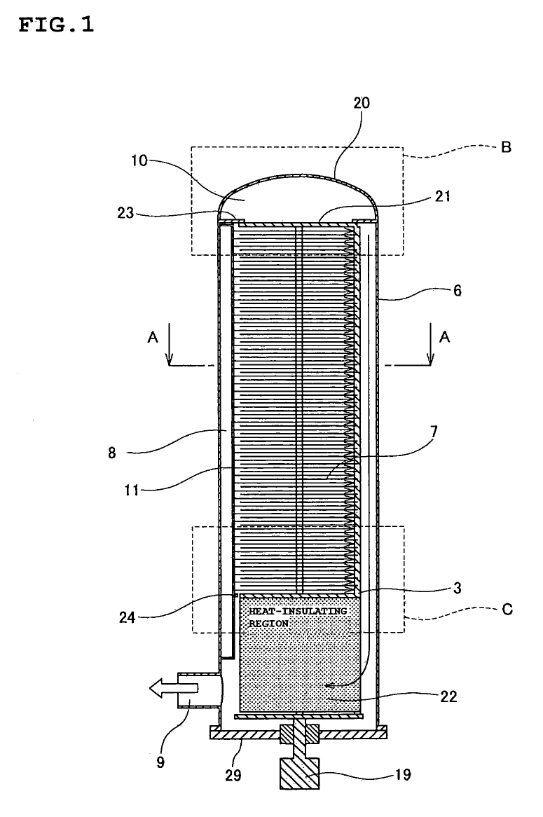

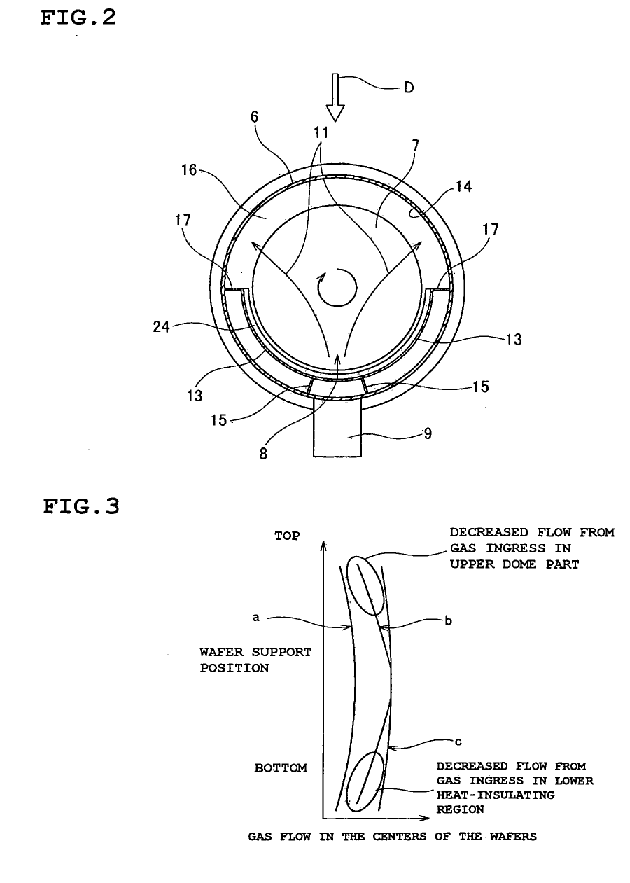

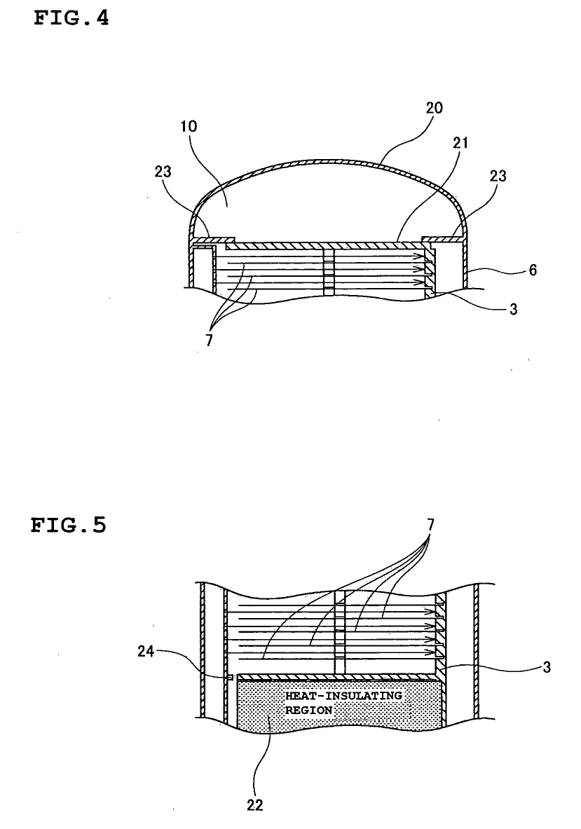

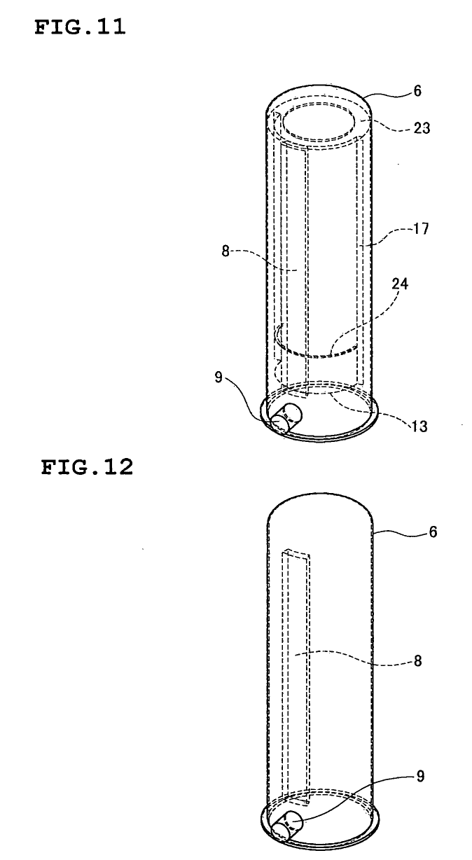

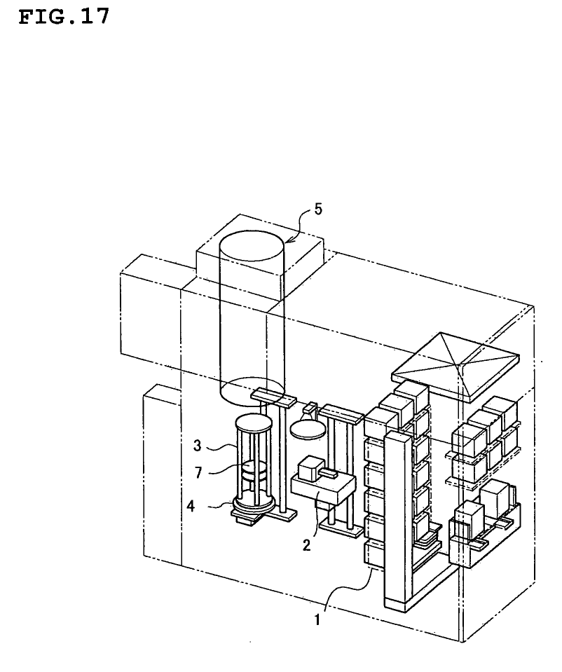

The configuration of the semiconductor processing apparatus pertaining to an embodiment of the present invention is described below in reference to the drawings. FIG. 17 is a comprehensive diagram of the configuration of the semiconductor processing apparatus according to an embodiment of the present invention. FIG. 11 is a perspective view showing the configuration of the heat processing furnace equipped with the semiconductor processing apparatus according to an embodiment of the invention. FIG. 1 is a schematic view of a vertical cross-section of the heat processing furnace equipped with the semiconductor processing apparatus according to an embodiment of the present invention. FIG. 2 is a schematic view of the section A-A of the heat processing furnace equipped with the semiconductor processing apparatus according to an embodiment of the present invention. FIG. 4 is an enlarged view of the configuration of region B of the heat processing furnace equipped with the semiconductor processing apparatus according to an embodiment of the present invention. FIG. 5 is an enlarged view of the configuration of region C of the heat processing furnace equipped with the semiconductor processing apparatus according to an embodiment of the present invention.

The semiconductor processing apparatus according to an embodiment of the present invention, as shown in FIG. 17, is equipped with a cassette stocker 1 that carries a wafer cassette that houses wafers 7 serving as substrates, a boat 3 that serves as the substrate support member that supports a plurality of wafers 7, wafer carrier 2 for carrying the wafers 7 between the cassette stocker 1 and the boat 3, a heat processing furnace 5 for processing the wafers, and a boat elevating/lowering part 4 for loading the boat 3 inside the heat processing furnace 5.

The heat processing furnace 5, as shown in FIG. 11, has a processing tube 6, a gas supply part 8, an exhaust opening 9 that serves as the exhaust part, a gas rectifying plate 13, and an upper gas infusion regulating plate 23 and lower gas infusion resulting plate 24 that serve as the gas flow regulating part. Although not shown in the drawing, a heater that serves as the heater for heating the wafers 7 that are loaded into the processing tube 6 is provided so as to surround the outer circumference of the processing tube 6. The configuration of the heat processing furnace 5 is described in detail below.

(Processing Tube)

The processing tube 6, as shown in FIG. 1, is configured so as to house, from below, the boat 3 serving as the substrate support member that supports a plurality of wafers 7 stacked at a prescribed pitch in the vertical direction. Specifically, the bottom end part of the processing tube 6 is open, and the upper end part of the processing tube 6 is formed as a dome part 20 that is sealed off in the form of a dome. The processing tube 6 is composed of a non-metallic material with high heat resistance, such as quartz (SiO₂) or silicon carbide (SiC). A processing chamber 10 for processing the wafers 7 is formed in the processing tube 6.

The bottom part of the boat 3 is supported by a heat-insulating cap that constitutes a heat-insulating region 22 that blocks heat conduction from the boat 3. The bottom end part of the heat-insulating cap that constitutes the heat-insulating region 22 is supported by a rotating shaft 19 of rotating part disposed so as to pass through a sealing cap 29 that serves as a lid body. A configuration is thus produced in which the boat 3 is loaded into the processing chamber 10 when the boat elevating/lowering part 4 elevates the sealing cap 29, and the bottom end part of the processing tube 6 is blocked in an air-tight fashion by the sealing cap 29. In addition, a configuration is produced in which, in the semiconductor processing step described below, it becomes possible to cause the wafers 7 to rotate inside the processing chamber 10 as shown in FIG. 2 by operating the rotating part.

(Gas Supply Part)

The gas supply part 8, as shown in FIG. 1, extends in the direction in which the wafers 7 are stacked in the processing tube 6, and has a plurality of gas supply openings. The gas supply part 8 is composed of a non-metallic material having high heat resistance such as quartz (SiO₂) or silicon carbide (SiC) as with the processing tube 6. The side wall 15 of the gas supply part 8, as shown in FIG. 2, is hermetically welded to the inner wall 14 of the processing tube 6. The vertical position, opening diameter, and number of the gas supply openings provided on the gas supply part 8 are adjusted appropriately so that gas can be supplied uniformly between each of the wafers 7 that is supported on the boat 3. As shown in FIG. 1, the gas supply part 8 is not restricted to a single system, and a plurality of systems may be provided. In addition, the gas that is supplied from the gas supply part 8 is not restricted to one type, as a plurality of types [may be used].

(Exhaust Opening)

The exhaust opening 9 that serves as the exhaust part opens onto the processing tube 6 as shown in FIG. 1. The exhaust opening 9 is connected to an evacuation pump (not shown) via a variable conductance valve (not shown), and a configuration is produced whereby the pressure in the processing chamber 10 can be adjusted as desired. In FIG. 11 and FIG. 1, the exhaust opening 9 is provided below the gas supply part 8, but the embodiments of the present invention are not limited to such embodiments, as the exhaust opening 9 may be disposed in the upper part or in the middle part of the processing tube 6, or may be disposed at a location that is opposite the gas supply part 8 with the carrying region of the wafers 7 interposed.

(Gas Rectifying Plate)

The gas rectifying plate 13, as shown in FIG. 2, is disposed in the space in between the penumbra of the wafers 7 supported on the boat 3 and the inner wall 14 of the processing tube 6, extending from the gas supply part 8 in the circumferential direction of the processing tube 6, and in the direction in which the wafers 7 are stacked.

Specifically, the gas rectifying plate 13 is disposed so as to proximally encompass the penumbra of the wafers 7 supported on the boat 3. The gas rectifying plate 13 is composed of a non-metallic material that has high heat resistance such as quartz (SiO₂) or silicon carbide (SiC), as with the processing tube 6. One end of the gas rectifying plate 13 is welded in an air-tight manner to the gas supply part 8. The side wall 17 that constitutes the other end part of the gas rectifying plate 13 is welded in an air-tight manner to the inner wall 14 of the processing tube 6. A configuration is thus produced in which ingress of gas does not readily occur into the space provided by the gas rectifying plate 13 (the space delineated by the gas rectifying plate 13, the gas rectifying plate 13 side wall 17, the side wall 15 of the gas supply part 8, and the inner wall 14 of the processing tube 6). Specifically, a configuration is produced in which, in the region in which the gas rectifying plate 13 is provided, the gas that has been supplied from the gas supply part 8 does not readily flow into (does not readily escape through) the space interposed between the penumbra of the wafers 7 and the inner wall 14 of the processing tube 6.

The gas rectifying plate 13 extends in the shape of a fan in the circumferential direction of the processing tube 6 from the gas supply part 8, and thus a space 16 in which the gas rectifying plate 13 is not present is formed as the space interposed between the circumferential edges of the wafers 7 supported on the boat 3 and the inner wall 14 of the processing tube 6, in a location opposite the gas supply part 8 with the carrying region of the wafers 7 interposed. This space 16 does not have any structural materials, and thus has a comparatively low gas flow resistance. For this reason, the gas that is supplied form the gas supply part 8 indicated by the designation 11, does not flow in the space interposed between the circumferential edges of the wafers 7 and the inner wall 14 of the processing tube 6 in the region in which the gas rectifying plate 13 is provided, but passes through the center region of the wafers 7 by flowing (penetrating) into the gaps of the wafers 7. After flowing towards the space 16 in which the gas rectifying plate 13 is not provided, [the gas] flows downward in the processing tube 6 and exhausts via the exhaust opening 9. Specifically, even though the pitch at which the wafers 7 are stacked is small (even though the flow resistance is large in the region in which the wafers 7 are carried), the flow resistance of the gas escape path at the circumferential edges of the gas supply part 8 is increased, and the flow resistance on the downstream side of the gas flow (specifically, in the space 16) is decreased, so that it is possible to supply a large quantity of gas to the center regions of the wafers 7.

In FIG. 2, the center angle of the fan shape that is constituted by the gas rectifying plate 13 is taken as 180°, but this center angle is freely adjusted along with the pitch at which the wafers 7 are stacked. However, if the center angle is too narrow, then the effects of the flow rectification described above will decrease, and the uniformity of the amount of gas supplied to the surfaces of the wafers 7 will decrease (decrease in amount of gas supplied to the centers of the wafers 7). When the center angle is too large, on the other hand, flow resistance is produced in the vertical direction in the space 16 in which the gas rectifying plate 13 is not provided, and there is a decrease in the uniformity of the amount of gas supplied between the wafers 7 (specifically, the amount of gas supplied to the wafers 7 supported in the upper part of the boat 3 is decreased and the amount of gas supplied to the wafers 7 supported in the bottom part of the boat 3 is increased). For this reason, the center angle of the fan shape constituted by the gas rectifying plate 13 is preferably set at 180° C. or greater and 240° C. or less.

In order to increase the efficiency of gas exchange or exhaust inside the processing tube 6, it is preferable to provide an opening on at least one end of the upper end part and lower end part of the gas rectifying plate 13 so that a state of a sealed enclosure is not obtained.

(Gas Flow Regulating Part)

The upper gas penetration regulating plate 23 and lower gas penetration regulating plate 24 serving as the gas flow regulating part are disposed in the space in the processing tube 6 that is above the top-most wafer 7 and the top-most gas supply opening, and in a space inside the processing tube 6 that is lower than the lowest wafer 7 and the lowest gas supply opening. The upper gas penetration regulating plate 23 and lower gas penetration regulating plate 24, as shown in FIGS. 4 and 5, are fixed to the inner wall 14 of the processing tube 6 and extend in the circumferential direction. The upper gas penetration regulating plate 23 and lower gas penetration regulating plate 24 are made from a non-metallic material having high heat resistance such as silicon (SiO₂) and silicon carbide (SiC), as with the processing tube 6.

Specifically, the upper gas penetration regulating plate 23 is configured in such a manner that when the inner wall 14 of the processing tube 6 is rotated one revolution from the gas supply part 8 in the circumferential direction, the gap between the inner wall 14 of the processing tube 6 and the outer circumference of a lid plate 21 of the boat 3 is sealed off. In order to increase the efficiency of exhaust and gas exchange in the processing tube 6, a configuration may be produced in which, for example, [the plate] does not extend to a location that faces the gas supply part 8 with the carrying region of the wafers 7 interposed (a location corresponding to the space 16).

In addition, the lower gas penetration regulating plate 24 is configured so as to extend in the circumferential direction through the inner wall 14 of the processing tube 6 from the gas supply part 8, and thus blocks off the gap between the inner wall 14 of the processing tube 6 and the bottom end part of the boat 3. The lower gas penetration regulating plate 24 is configured so that the space 16 that forms the gas flow path is not blocked and so as not extend to a position that is opposite the gas supply part 8 with a carrying position of the wafers 7 interposed (space 16). In FIG. 2, for example, the lower gas penetration regulating plate 24 extends only into the space in which the gas rectifying plate 13 is provided.

In comparison to the carrying region of the wafers 7, the flow resistance is lower in the space between the lid plate 21 of the boat 3 and the dome part 20 of the processing tube 6 (the space above the region in which the wafers 7 are carried) and in the heat-resistant region 22 in which the heat-resistant cap 3a is provided (the space below the region in which the wafers 7 are carried). For this reason, conversely, when the upper gas penetration regulating plate 23 and lower gas penetration regulating plate 24 are not provided, the gas that has been supplied in the vicinity of the lower part and in the vicinity of the upper part of the region in which the wafers 7 are carried will tend to flow (tend to be released) through these spaces. Thus, in this case, the amount of gas supplied to the wafers 7 supported in the upper part and lower part of the boat 3 will be smaller than the amount of gas supplied to the wafers 7 that are supported at the center of the boat 3.

However, in this embodiment, an upper gas penetration regulating plate 23 and a lower gas penetration regulating plate 24 are provided as the gas flow regulating part. For this reason, the gas indicated by designation 11 that is supplied from the gas supply part 8 flows (penetrates) into the gaps of the wafers 7 without flowing into the heat-insulating region 22 or the space between the lid plate 21 of the boat 3 and the dome part 20 of the processing tube 6. [The gas] passes through the center region of the wafers 7, flows towards the space 16 in which the gas rectifying plate 13 is not provided, and then flows downwards in the processing tube 6 and exhausts via the exhaust opening 9. Specifically, even though the pitch at which the wafers 7 are stacked is small (even though the flow resistance is large in the region in which the wafers 7 are carried), the flow resistance of the release path of the gas in the upper and lower spaces of the boat 3 is high, and the flow resistance on the down-flow side of the gas flow (specifically, the space 16) is small. A large quantity of gas can thus be supplied uniformly with respect to each of the wafers 7, regardless of the support position (height position) in the boat 3.

### (2) Semiconductor Processing Step

A description is presented next concerning the method for forming a thin film on the wafer 7 and for forming an oxide film on the surface of the wafer 7 as one of the steps of producing semiconductor devices. This method is carried out using the semiconductor processing apparatus equipped with the heat processing furnace 5 described above.

(Substrate Loading Step)

First, the boat elevating/lowering part 4 is operated (lowered) and the boat 3 is unloaded from the heat processing furnace 5. Next, the wafer carrier 2 is used, and the wafers 7 are carried to the boat 3 from the cassette stocker 1 housing the wafers 7 to be processed. A plurality of wafers 7 are supported in the boat 3 in a state of being stacked at a prescribed pitch in the vertical direction. Next, the boat elevating/lowering part 4 is operated (elevated), and the boat 3 is loaded into the heat processing furnace 5. The lower end of the processing tube 6 is closed in an air-tight manner by the seal cap 29.

Next, the rotating part 19 is operated (rotated) and the wafers 7 are made to rotate inside the processing tube 6. Next, the interior of the processing tube 6 that has been sealed in an air-tight manner exhausts via the exhaust opening 9, and the pressure in the processing tube 6 is reduced. In addition, the heater unit (not shown) that is disposed externally with respect to the processing tube 6 is operated, and the surfaces of the wafers 7 are heated.

In the step in which the above substrates are loaded, inert gas such as N₂ or He is continually made to flow into the processing tube 6 from the gas supply part 8. As a result, the oxygen concentration in the processing tube 6 decreases, and, accordingly, it is possible to inhibit particles (impurities) and metal contaminants from entering into the processing tube 6 and adhering to the wafers 7.

(Semiconductor Processing Step)

Next, the interior of the processing tube 6 exhausts via the exhaust opening 9, and the wafers 7 are processed by supplying a processing gas as such as a film formation gas or oxidation gas into the processing tube 6 from the gas supply part 8.

In the step in which the above substrates are processed, the flow of processing gas supplied to the processing tube 6 is inhibited by appropriately adjusting the gas flow resistance in the processing tube 6 using the gas rectifying plate 13, and the upper gas penetration regulating plate 23, and the lower gas penetration regulating plate 24, which are used as gas flow regulating parts.

Specifically, as indicated by designation 11, the processing gas that has been supplied from the gas supply part 8 flows (penetrates) into the gaps of the wafers 7 and through the center regions of the wafers 7 without flowing in the space between the penumbra of the wafers 7 and the inner wall 14 of the processing tube 6 in the region where the gas rectifying plate 13 is provided. After flowing towards the space 16 where the gas rectifying plate 13 is not provided, the gas flows downward in the processing tube 6 and exhausts via the exhaust opening 9. Specifically, the flow resistance is increased in the escape pathway of the gas at the circumferential edge of the gas supply part 8 and is reduced on the downstream side of the gas flow (specifically, the space 16), whereby a larger amount of gas is supplied to the center region of the wafers 7.

As indicated by designation 11, the gas that is supplied from the gas supply part 8 flows (penetrates) into the gaps of the wafers 7 and passes through the center regions of the wafers 7 without flowing to the heat-insulating region 22 or the space between the lid plate 21 of the boat 3 and the dome part 20 of the processing tube 6. [The gas] then flows towards the space 16 in which the gas rectifying plate 13 is not provided and downwards inside the processing tube 6, before exhausting via the exhaust opening 9. Specifically, increasing the flow resistance of the escape path of the gas in the upper and lower spaces of the boat 3 and reducing the flow resistance on the downstream side of the gas flow (specifically, the space 16) causes more of the gas to be supplied uniformly to each of the wafers 7 regardless of the support position (height position) in the boat 3.

Once the wafers 7 have finished being processed, the processing tube 6 continues to be exhausted while the supply of processing gas to the processing tube 6 is halted. At this time, inert gas is preferably supplied from the gas supply part 8 to the processing tube 6, thereby replacing the atmosphere of the processing tube 6 with inert gas.

(Substrate Removal Step)

Next, the boat 3 supporting the processed wafers 7 is unloaded from the processing tube 6 to complete the semiconductor steps in this embodiment.

### (3) Effects of the Embodiment

One or more of the following effects (a) to (f) is achieved in this embodiment.

(a) The heat processing furnace 5 in this embodiment is provided in the space between the penumbra of the wafers 7 supported in the boat 3 and the inner wall 14 of the processing tube 6, and the gas rectifying plate 13 is provided so as to extend from the gas supply part 8 in the circumferential direction of the processing tube 6 and along the direction in which the wafers 7 are stacked. For this reason, the gas that is supplied from the gas supply part 8 flows (penetrates) into the gaps of the wafers 7 without flowing into the space interposed between the penumbra of the wafers 7 and the inner wall 14 of the processing tube 6 in the region where the gas rectifying plate 13 is provided, passes through the center regions of the wafers 7, and flows towards the space 16 in which the gas rectifying plate 13 is not provided. [The gas] then flows downwards inside the processing tube 6 and exhausts via the exhaust opening 9. Specifically, even though the pitch at which the wafers 7 are stacked is small (even though the flow resistance is large in the region in which the wafers 7 are carried), more gas can be supplied to the center regions of the wafers 7 by increasing the flow resistance of the escape path of the gas at the circumferential edges of the gas supply part 8 and decreasing the flow resistance on the downstream side of the gas flow (specifically, the space 16). As a result, the film thickness of the thin films formed on the wafers 7 can be made more uniform across the entire surfaces of the wafers 7.

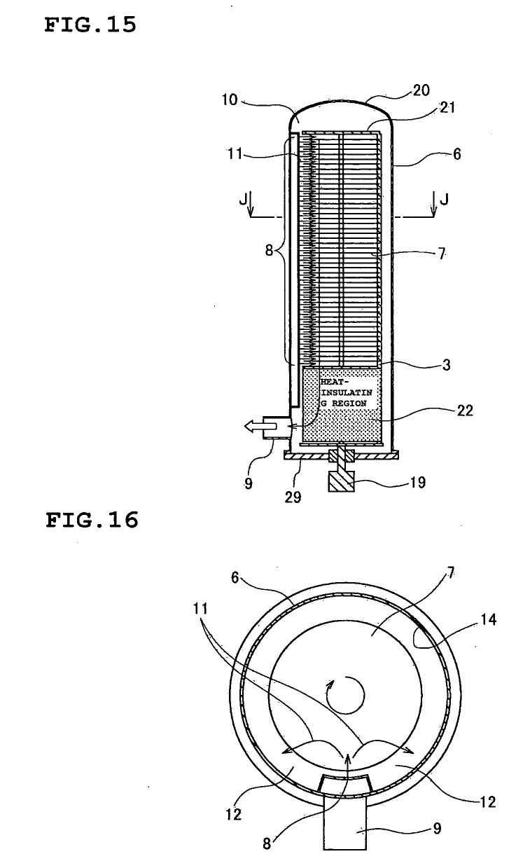

For purposes of reference, the configuration of a conventional heat processing furnace 5 provided with a semiconductor processing apparatus will be described in reference to the figures. FIG. 12 is a perspective view showing the structure of a conventional heat processing furnace 5 provided with a semiconductor processing apparatus. FIG. 15 is a schematic sectional view of a conventional heat processing furnace 5 provided with a semiconductor processing apparatus. FIG. 16 is a schematic J-J sectional view of the conventional heat processing furnace 5 provided with a semiconductor processing apparatus. The conventional heat processing furnace 5 is not provided with a gas rectifying plate 13, and the width of the space 12 interposed between the penumbra of the wafers 7 supported on the boat 3 and the inner wall 14 of the processing tube 6 is approximately constant at the external circumference of the wafers 7. The flow resistance in the space 12 is thus larger than the flow resistance in the region in which the wafers 7 are carried. For this reason, when the pitch at which the wafers 7 are stacked is small (when the flow resistance with respect to gas is large), the gas that has been supplied from the gas supply part 8 flows in the space 12 without flowing (penetrating) into the gaps of the wafers 7, and there are cases where the relative [amount of] gas that is supplied to the center regions of the wafers 7 is decreased. As a result, there are cases where the thickness of the thin films formed on the wafers 7 is larger in the penumbra of the wafers 7 and thinner in the center parts.

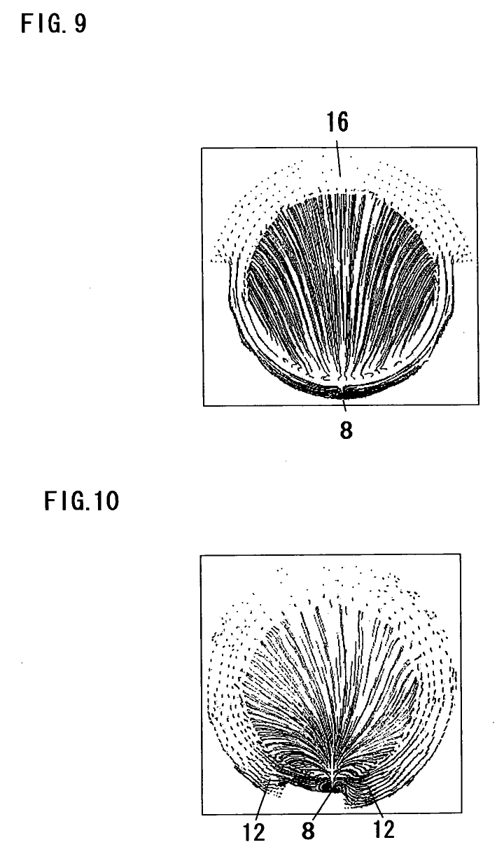

FIG. 10 shows the results of simulations concerning gas flow in a conventional heat processing furnace. FIG. 9 shows the results of simulations concerning gas flow in the heat processing furnace of this embodiment. As shown in FIG. 10, with the conventional heat processing device 5, the gas that is supplied from the gas supply part 8 to the processing tube 6 flows in the space 12 interposed between the penumbra of the wafers 7 supported on the boat 3 and the inner wall 14 of the processing tube 6, without flowing (penetrating) into the gaps of the wafers 7. It is thus seen that the relative [amount of] gas that is supplied to the center regions of the wafers 7 is decreased. As shown in FIG. 9, with the heat processing furnace 5 of this embodiment, on the other hand, the flow of gas from the gas supply part 8 to the space 16 in which the gas rectifying plate 13 is not provided predominates, and more of the gas thus passes between the wafers 7. It is thus seen that more of the gas is supplied to the center regions of the wafers 7. Specifically, under conditions in which the pressure inside the processing tube 6 is 60 Pa, the treatment temperature is 550° C., the processing gas is NH₃, and the gas supply is 6 slm, the gas flow rate at the centers of the wafers 7 in the conventional heat processing furnace 5 is 0.15 m/sec, whereas the gas flow rate at the centers of the wafers 7 in the heat processing furnace 5 of this embodiment is 0.30 m/sec.

(b) The heat processing furnace 5 of this embodiment is provided with an upper gas penetration regulating plate 23 and a lower gas penetration regulating plate 24 serving as the gas flow regulating part. For this reason, the gas that is supplied from the gas supply part 8 flows (penetrates) into the gaps of the wafers 7 without flowing into the heat-insulating region 22 or the space between the lid plate 21 of the boat 3 and the dome part 20 of the processing tube 6. [The gas] passes through the center regions of the wafers 7, flows towards the space 16 in which the gas rectifying plate 13 is not provided, and then flows downwards in the processing tube 6 and exhausts via the exhaust opening 9. Specifically, even though the pitch at which the wafers 7 are stacked is small (even though the flow resistance is large in the region in which the wafers 7 are carried), the flow resistance of the release path of the gas in the upper and lower spaces of the boat 3 is high, and the flow resistance on the down-flow side of the gas flow (specifically, the space 16) is small. Consequently, a larger quantity of gas can be supplied uniformly with respect to each of the wafers 7, regardless of the support position (height position) in the boat 3.

On the other hand, in a conventional heat processing furnace 5, as shown in FIGS. 12 and 15, an upper gas penetration regulating plate 23 and lower gas penetration regulating plate 24 are not provided as the gas flow regulating part. For this reason, there are cases where the gas that is supplied near the upper and lower parts of the boat 3 flows (escapes) into the heat insulating region 22 or the space between the lid plate 21 of the boat 3 and the dome part 20 of the processing tube 6. As a result, the amount of gas supplied to the wafers 7 that are supported in the top part and the bottom part of the boat 3 is smaller than the amount of gas supplied to the wafers 7 that are supported at the center of the boat 3, and the thickness of the thin films formed on the wafers 7 will be irregular depending on the support position (height position) of the wafers 7 in the boat 3 (thinner in the upper and lower sections of the boat 3 and thicker in the center section of the boat 3).

FIG. 3 shows the relationship between the height position of the wafers and the flow rate of gas passing through the centers of the wafers. In FIG. 3, the curve indicated by a shows the above relationship for a conventional heat processing furnace 5 in which the wafers 7 are stacked with a large pitch. The curve indicated by b shows the above relationship for a case in which the pitch at which the wafers are stacked is small, and only a gas rectifying plate 13 is provided in the heat processing furnace 5, without an upper gas penetration regulating plate 23 or lower gas penetration regulating plate 24 being provided as the gas flow regulating part. In addition, the curve indicated by c shows the above relationship for the heat processing furnace 5 according to this embodiment in which the pitch at which the wafers 7 are stacked is equivalent to that of the curve b, and a gas rectifying plate 13, upper gas penetration regulating plate 23, and lower gas penetration regulating plate 24 are provided in the heat processing furnace 5.

As is shown by the curve indicated by a, when the pitch at which the wafers 7 are stacked is large, the flow resistance of the region in which the wafers 7 are supported is comparatively small, and it is thus seen that the speed of the gas passing through the centers of the wafers 7 is comparatively uniform. However, as is shown by the curve indicated by b, when the pitch at which the wafers 7 are stacked is small, the flow resistance of the region in which the wafers 7 are supported is comparatively large, and it is thus seen that the flow rate of gas passing through the centers of the wafers 7 becomes nonuniform. Specifically, it can be seen that the gas that is supplied in the vicinity of the top and bottom parts of the boat 3 flows into the space between the lid plate 21 of the boat 3 and the dome part 20 of the processing tube 6 or in the heat-insulating region 22 in which the heat-insulating cap 3a is provided, and the flow rate of the gas in the vicinity of the top and bottom parts of the boat 3 is thus decreased. In contrast, in accordance with the curve indicated by c (the current embodiment), because the upper gas penetration regulating plate 23 and lower gas penetration regulating plate 24 increase the flow resistance of the escape path of the gas in the vicinity of the top and bottom parts of the boat 3, it is seen that a larger amount of gas is uniformly supplied to each of the wafers 7, regardless of the support position (height position) in the boat 3.

(c) As described above, the heat processing furnace 5 according to this embodiment is equipped with a gas rectifying plate 13, an upper gas penetration regulating plate 23, and a lower gas penetration regulating plate 24. Specifically, a space 16 having low flow resistance is provided only on the down-stream side of the gas flow (location opposite the gas supply part 8, with the region in which the wafers 7 are carried interposed), and the out-flow destination for the gas in the processing tube 6 (region in which there is smaller flow resistance than in the wafer 7 carrying region, through which the processing gas escapes) is eliminated. As a result, it is possible to increase the gas flow rate passing between the wafers 7. For example, as shown in FIG. 3, when the pitch at which the wafers 7 are stacked is small, the curve indicated by c in which the heat processing furnace 5 is equipped with a gas rectifying plate 13, an upper gas penetration regulating plate 23 and a lower gas penetration regulating plate 24 has a higher gas flow rate than the curve indicated by a. Even with the curve indicated by b in which only a gas rectifying plate 13 is provided, the flow rate of the gas is higher than the curve indicated by a. Consequently, it is possible to increase the amount of gas supplied per unit time to the wafers 7, thereby increasing the film formation rate and improving semiconductor processing productivity.

(d) With the heat processing furnace 5 according to this embodiment, as described above, the gas out-flow destination (region into which the gas can escape) is eliminated from the processing tube 6. As a result, it is possible to effectively utilize the processing gas and to decrease the cost of substrate treatment.

(e) With the heat processing furnace 5 of this embodiment, the positional relationship between the gas supply part 8 and exhaust opening 9 is set as desired, and the gas supply part 8 and exhaust opening 9 can be provided in the same direction. For this reason, it is possible to maintain the gas supply part 8 and exhaust opening 9 from one direction, allowing improvement in semiconductor processing apparatus maintenance.

### Additional Embodiment of the Present Invention

The present invention is not limited to the embodiment presented above, and is described below based on another embodiment.

(1) The gas flow regulating part according to the above embodiment is fixed to the inner wall 14 of the processing tube 6 and comprises an upper gas penetration regulating plate 23 and lower gas penetration regulating plate 24 extending in a circumferential direction. However, the present invention is not limited to such embodiments. Specifically, the gas flow regulating part may be a group comprising a plurality of plates that are stacked in the vertical direction at a pitch that is narrower than the pitch at which the wafers 7 are stacked.

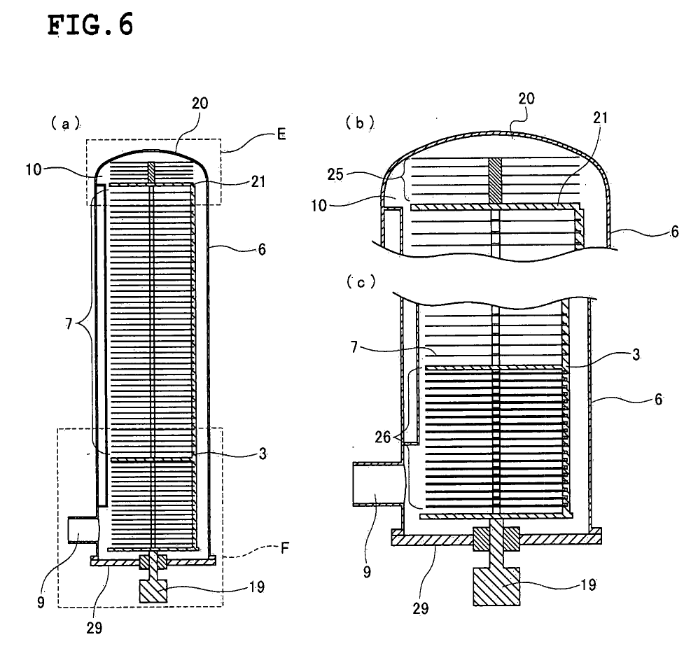

FIG. 6 shows the structure of the heat processing furnace 5 equipped with the semiconductor processing apparatus according to another embodiment of the present invention. FIG. 6A is a vertical sectional view of the heat processing furnace 5, FIG. 6B is a partially enlarged view of region E, and FIG. 6C is a partially enlarged view of the region F. According to FIG. 6, the gas flow regulating part of this embodiment is composed of an upper part plate group 25 that is provided in the space between the lid plate 21 of the boat 3 and the dome part 20 of the processing tube 6, and a lower part plate group 26 that is provided in the heat-insulating region 22 towards the bottom of the boat 3. The respective plates that constitute the upper part plate group 25 and lower part plate group 26 are composed, for example, of polygonal plates or circular plates of sizes that are approximately equivalent to the wafers 7. The pitch at which the plates that constitute the upper part plate group 25 and lower part plate group 26 are stacked is set to be narrower than the pitch at which the wafers 7 supported on the boat 3 are stacked, and a configuration is produced whereby the flow resistance of the upper part plate group 25 and lower part plate group 26 exceeds the flow resistance in the region in which the wafers 7 are carried.

In this embodiment, similar effects as in (b) of the embodiment described above can be obtained. Specifically, the gas that is supplied from the gas supply part 8 flows (penetrates) into the gaps of the wafers 7 without flowing into the heat-insulating region 22 or the space between the lid plate 21 of the boat 3 and the dome part 20 of the processing tube 6. [The gas] passes through the center regions of the wafers 7, flows towards the space 16 in which the gas rectifying plate 13 is not provided, and then flows downwards in the processing tube 6 and exhausts via the exhaust opening 9. Specifically, the flow resistance of the release path of the gas in the upper and lower spaces of the boat 3 is high, and the flow resistance on the down-flow side of the gas flow (specifically, the space 16) is low, and thus a larger quantity of gas can be supplied uniformly with respect to each of the wafers 7, regardless of the support position (height position) in the boat 3.

In this embodiment, the thickness, number, and stacking pitch of the plates that constitute the upper part plate group 25 and lower part plate group 26 can be changed, thereby allowing the flow resistance to be appropriately adjusted.

In this embodiment, it is also possible to facilitate loading of the upper part plate group 25 and lower part plate group 26 into the processing tube 6 by installing the upper part plate group 25 and lower part plate group 26 in the upper and lower [sections] of the boat 3, thus providing them on the interior of the boat 3. Maintenance of the semiconductor processing apparatus can thus be improved.

In this embodiment, because the plates that constitute the lower part plate group 26 are composed of a heat-insulating material, it is possible to provide heat-insulating capacity whereby the seal cap 29 is shielded from thermal radiation and thermal conduction from the boat 3.

(2) In the above embodiment, in order to increase the flow resistance in the space between the lid plate 21 of the boat 3 and dome part 20 in the upper part of the processing tube 6, a gas flow regulating part that inhibits gas from entering this space is provided. However, the present invention is not limited to such embodiments. The flow resistance can also be increased by narrowing the above space by bringing the lid plate 21 of the boat 3 and the dome part 20 in the upper part of the processing tube 6 into proximity. Specifically, it is possible to supply a greater quantity of gas uniformly to each of the wafers 7 regardless of the support position (height position) in the boat 3.

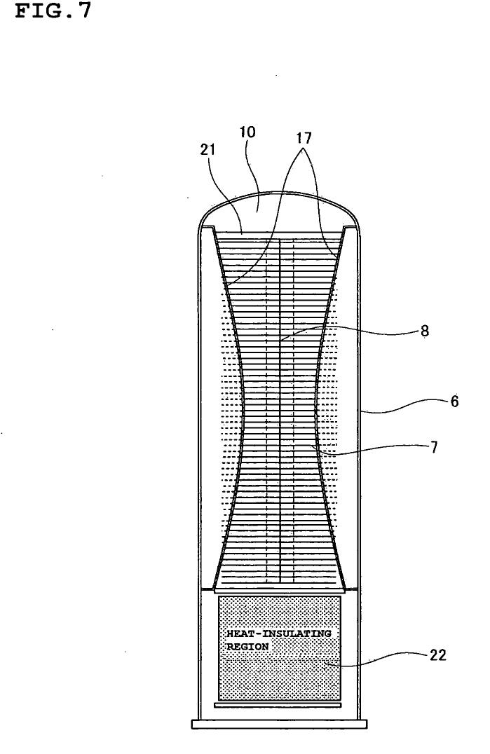

(3) With the heat processing furnace 5 according to the above embodiment, the gap in the circumferential direction of the processing tube 6 is constant in the height direction (wafer 7 stacking direction) in the space interposed between the penumbra of the wafers 7 supported in the boat 3 and the inner wall 14 of the processing tube 6, or in the space 16 in which the gas rectifying plate 13 and gas supply part 8 are not provided. Specifically, the gap between the side wall 17 and the gas rectifying plate 13 with the space 16 interposed is constant in the height direction (stacking direction of the wafers 7). However, the present invention is not limited to such embodiments. Specifically, as shown in FIG. 7, regarding the space 16 referred to above, the space in the circumferential direction of the processing tube 6 in the central region in the direction in which the wafers 7 are stacked may be configured so as to be smaller than the gap in the circumferential direction of the processing tube 6 in the regions above and below the central region.

FIG. 7 is a diagram showing the heat processing furnace 5 provided with the semiconductor processing apparatus according to another embodiment of the present invention, and is a vertical sectional view of the configuration as seen from direction D in FIG. 2. According to FIG. 7, a configuration is produced in which the gap between the side wall 17 and the gas rectifying plate 13 with the space 16 interposed is narrow in the central region in the stacking direction of the wafers 7 and is narrow in the upper and lower regions in the stacking direction of the wafers 7, thus giving the space 16 a drum shape.

According to this embodiment, the flow resistance in the height direction (wafer 7 stacking direction) in the space 16 is adjusted, so that gas can be supplied uniformly to each of the wafers 7, regardless of the support location (height location) in the boat 3. Specifically, the flow resistance in the space 16 is decreased in the upper and lower regions of the boat 3, the flow resistance in the space 16 in the central region of the boat 3 is increased, and supply of gas to the wafers 7 is thus promoted in the upper and lower regions of the boat 3, while the supply of gas to the wafers 7 supported in the central region of the boat 3 is restricted. The amount of gas supplied to each wafer 7 can thus be made more uniform, regardless of the support position (height position) in the boat 3.

(4) In the above embodiment, one end part of the gas rectifying plate 13 is hermetically welded to the gas supply part 8, and the side wall 17 that constitutes the other end part of the gas rectifying plate 13 is hermetically welded to the inner wall 14 of the processing tube 6. However, the present invention is not limited to such embodiments. Specifically, the gas rectifying plate 13 can be securely welded at one or more locations on the inner wall 14 of the processing tube 6, and may be provided with gaps interposed with respect to the inner wall 14 of the processing tube 6 at the locations that are not welded.

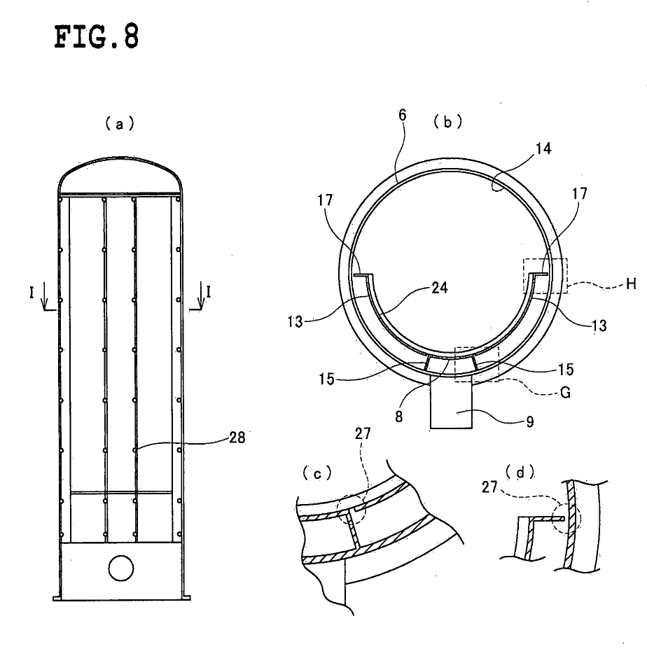

FIG. 8 shows the structure of the heat processing furnace equipped with the semiconductor processing apparatus according to another embodiment of the present invention. FIG. 8A shows a scheme in which the gas rectifying plate is securely welded at one or more locations to the inner wall of the processing tube, FIG. 8B is a schematic view of the section I-I of the heat processing furnace, FIG. 8C is an enlarged view of the configuration of region G, and FIG. 8D is an enlarged view of the configuration of region II. In accordance with FIG. 8A, one end part of the gas rectifying plate 13 according to this embodiment is securely welded at one or more locations 28 to the gas supply part 8, and the side wall 17 that constitutes the other end part of the gas rectifying plate 13 is securely welded at one or more locations 28 to the inner wall 14 of the processing tube 6. These welds are produced, for example, by spot welding. In addition, in accordance with FIGS. 8B to 8D, the gas rectifying plate 13 according to this embodiment is disposed with a gap 27 of, for example, about 2 mm with respect to the gas supply part 8 or the inner wall 14 of the processing tube 6 in the locations 28 that are not welded.

In accordance with this embodiment, it is possible to limit damage to the processing tube 6 or gas rectifying plate 13 caused by thermal warping occurring during welding (weld warping). In addition, it is possible to limit damage to the processing tube 6 or gas rectifying plate 13 due to thermal stress when the interior of the processing tube 6 is heated during substrate treatment.

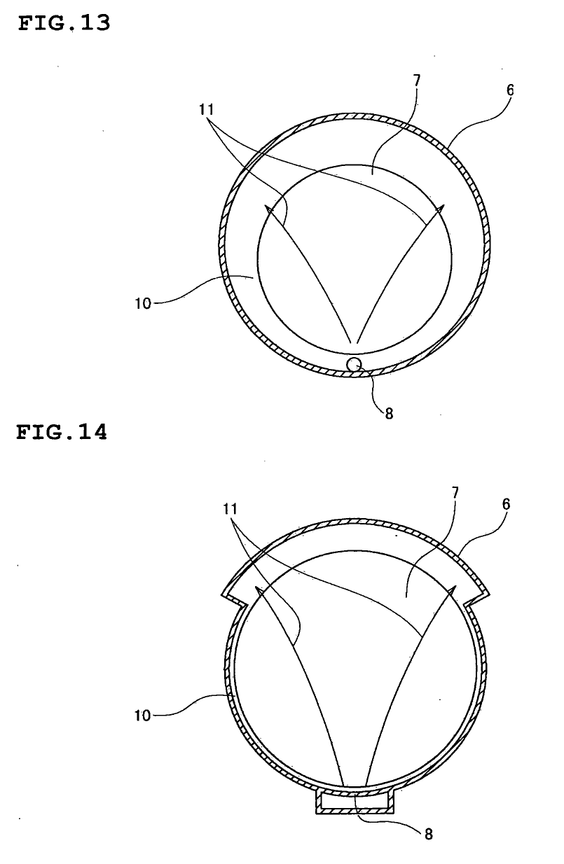

(5) In the above embodiment, the gas flow resistance in the processing tube is adjusted appropriately by providing the gas rectifying plate 13 in the prescribed location in the processing tube 6, but the present invention is not limited to the above configuration. Specifically, a configuration can be produced in which the gap between the inner wall 14 of the processing tube 6 and the penumbra of the wafers 7 supported on the boat 3 is made narrow in the vicinity of the circumferential edge of the gas supply part 8, and a configuration can be produced in which [this gap] is larger on the side opposite the carrying region of the wafers 7. For example, as shown in FIG. 13, the carrying region of the wafers 7 can be shifted to the side of the gas supply part 8, and can be disposed so that the penumbra of the wafers 7 supported in the boat 3 are brought into proximity with the inner wall 14 of the processing tube 6 in the vicinity of the gas supply part 8. In addition, for example, as shown in FIG. 14, a configuration can be produced in which the inner diameter of the processing tube 6 is made smaller in the vicinity of the gas supply part 8. In conjunction therewith, a configuration can be produced in which the inner diameter of the processing tube 6 is increased on the opposite side of the carrying region of the wafers 7.

In accordance with this embodiment, it is possible to achieve similar effects as in (a) of the above embodiment. Specifically, the gas that is supplied from the gas supply part 8 flows (penetrates) into the gaps of the wafers 7 without flowing into the space interposed between the penumbra of the wafers 7 and the inner wall 14 of the processing tube 6 in the region where the gas rectifying plate 13 is provided, passes through the center regions of the wafers 7, and flows towards the space 16 in which the gas rectifying plate 13 is not provided. [The gas] then flows downwards inside the processing tube 6 and exhausts via the exhaust opening 9. As a result, for example, the film thickness of the thin films formed on the wafers 7 can be made more uniform across the entire surfaces of the wafers 7.

(6) The present invention is suitable for use in all semiconductor processing apparatuses, such as CVD devices, oxide film formation devices, diffusion devices, annealing device, and batch-type plasma devices.

(7) The present invention has been described using wafers 7 as examples of substrates, but the substrates may also be photomasks, printed wiring boards, liquid crystal panels, optical disks, and magnetic disks.

Embodiments of the present invention were described above, but the present invention is not limited to the above embodiments and may be modified accordingly within a scope that would be evident to a person skilled in the art.

### Additional Embodiment of the Invention

An additional embodiment of the present invention is included below.

A first aspect of the present invention provides a semiconductor processing apparatus comprising: a processing tube for housing a substrate support member that supports a plurality of substrates stacked at a prescribed pitch in a vertical direction; a gas supply part that extends in a direction in which the substrates are stacked in the processing tube and that has a plurality of gas supply openings; an exhaust part that opens onto the processing tube; a gas rectifying plate that is disposed in a space between a penumbra of the substrates supported on the substrate support member and an inner wall of the processing tube, and that extends from the gas supply part in a circumferential direction of the processing tube and in the direction in which the substrates are stacked; and a gas flow regulating part disposed in a space in the processing tube that is above a top-most gas supply opening and a top-most substrate and in a space in the processing tube that is below a bottom-most substrate and a bottom-most gas supply opening.

A second aspect of the present invention provides a semiconductor processing apparatus of the first aspect, wherein the gas flow regulating part is a regulating plate that is fixed to the inner wall of the processing tube and that extends in the circumferential direction.

A third aspect of the present invention provides the semiconductor processing apparatus of the first aspect, wherein the gas flow regulating part is a group of a plurality of plates that are stacked in a vertical direction at a pitch that is less than the pitch at which the substrates are stacked.

A fourth aspect of the present invention provides the semiconductor processing apparatus of the any of the first through third aspects, wherein the space that is disposed between the penumbra of the substrates supported on the substrate support member and the inner wall of the processing tube, and that does not have the gas supply part and the gas rectifying plate is configured so that a gap in a circumferential direction of the processing tube in a center region in the direction in which the substrates are stacked is smaller than a gap in a circumferential direction of the processing tube in regions that are above and below the center region.

A fifth aspect of the present invention provides the semiconductor processing apparatus according to any of the first through fourth aspects, wherein the gas rectifying plate is securely welded at one or more locations on the inner wall of the processing tube, and is disposed across a gap with respect to the inner wall of the processing tube in locations other than where the welding has been performed.

A sixth aspect of the present invention provides the semiconductor processing apparatus according to any of the first through fifth aspects, wherein the gas rectifying plate extends from the gas supply part in a fan shape having a center angle of from 120° or greater to 240° or less along the circumferential direction of the processing tube.

A seventh aspect of the present invention provides the semiconductor processing apparatus according to any of the first through sixth aspects, wherein an opening is provided on at least one of a top end part or bottom end part of the gas rectifying plate.

An eighth aspect of the present invention provides a manufacturing method of a semiconductor device, comprising: loading an inside of a processing tube with a substrate support member that supports a plurality of substrates stacked at a prescribed pitch in a vertical direction; processing the substrates by supplying gas into the processing tube from a gas supply part that extends along the direction in which the substrates are stacked in the processing tube and that is equipped with a plurality of gas supply openings while exhausting an inside of the processing tube from an exhaust part that opens onto the processing tube; and unloading the substrate support member that supports the treated substrates from the inside of the processing tube; wherein during the processing of the substrates, control is performed over respective flows of gas supplied to an inside of the processing chamber using a gas rectifying plate that is provided in a space between a penumbra of the substrates supported in the substrate support member and an inner wall of the processing tube and that extends from the gas supply part along a circumferential direction of the processing tube and the direction in which the substrates are stacked, and a gas flow regulating part disposed in a space inside the processing tube that is above a top-most gas supply opening and a top-most substrate and in a space inside the processing tube that is lower than a bottom-most substrate and a bottom-most gas supply opening.

1. A semiconductor processing apparatus, comprising:
a processing tube for housing a substrate support member that supports a plurality of substrates stacked at a prescribed pitch in a vertical direction;
a gas supply part that extends in a direction in which said substrates are stacked in said processing tube and that has a plurality of gas supply openings;
an exhaust part that opens onto said processing tube;
a gas rectifying plate that is disposed in a space between a penumbra of the substrates supported on said substrate support member and an inner wall of said processing tube, and that extends from said gas supply part in a circumferential direction of said processing tube and in the direction in which said substrates are stacked; and
a gas flow regulating part disposed in a space in said processing tube that is above a top-most gas supply opening and a top-most substrate and in a space in said processing tube that is below a bottom-most substrate and a bottom-most gas supply opening.

2. The semiconductor processing apparatus according to claim 1, wherein said gas flow regulating part is a regulating plate that is fixed to the inner wall of said processing tube and that extends in the circumferential direction.

3. The semiconductor processing apparatus according to claim 1, wherein said gas flow regulating part is a group of a plurality of plates that are stacked in a vertical direction at a pitch that is less than the pitch at which said substrates are stacked.

4. The semiconductor processing apparatus according to claim 1, wherein the space that is disposed between the penumbra of the substrates supported on said substrate support member and the inner wall of said processing tube, and that does not have said gas supply part and said gas rectifying plate is configured so that a gap in a circumferential direction of said processing tube in a center region in the direction in which said substrates are stacked is smaller than a gap in a circumferential direction of said processing tube in regions that are above and below said center region.

5. The semiconductor processing apparatus according to claim 1, wherein said gas rectifying plate is securely welded at one or more locations on the inner wall of said processing tube, and is disposed across a gap with respect to the inner wall of said processing tube in locations other than where the welding has been performed.

6. The semiconductor processing apparatus according to claim 1, wherein said gas rectifying plate extends from said gas supply part in a fan shape having a center angle of from 120° or greater to 240° or less along the circumferential direction of said processing tube.

7. The semiconductor processing apparatus according to claim 1, wherein an opening is provided on at least one of a top end part or bottom end part of said gas rectifying plate.

8. The semiconductor processing apparatus according to claim 4, wherein said gas rectifying plate is securely welded at one or more locations on the inner wall of said processing tube, and is disposed across a gap with respect to the inner wall of said processing tube in locations other than where the welding has been performed.

9. The semiconductor processing apparatus according to claim 4, wherein said gas rectifying plate extends from said gas supply part in a fan shape having a center angle of from 120° or greater to 240° or less along the circumferential direction of said processing tube.

10. The semiconductor processing apparatus according to claim 5, wherein said gas rectifying plate extends from said gas supply part in a fan shape having a center angle of from 120° or greater to 240° or less along the circumferential direction of said processing tube.

11. The semiconductor processing apparatus according to claim 4, wherein an opening is provided on at least one of a top end part or bottom end part of said gas rectifying plate.

12. The semiconductor processing apparatus according to claim 5, wherein an opening is provided on at least one of a top end part or bottom end part of said gas rectifying plate.

13. The semiconductor processing apparatus according to claim 6, wherein an opening is provided on at least one of a top end part or bottom end part of said gas rectifying plate.

14. A manufacturing method of a semiconductor device comprising:
loading an inside of a processing tube with a substrate support member that supports a plurality of substrates stacked at a prescribed pitch in a vertical direction;
processing the substrates by supplying gas into said processing tube from a gas supply part that extends along the direction in which said substrates are stacked in said processing tube and that is equipped with a plurality of gas supply openings while exhausting an inside of said processing tube from an exhaust part that opens onto said processing tube; and
unloading said substrate support member that supports the treated substrates from the inside of said processing tube; wherein
during the processing of said substrates, control is performed over respective flows of gas supplied to an inside of said processing chamber using a gas rectifying plate that is provided in a space between a penumbra of the substrates supported in said substrate support member and an inner wall of said processing tube, and that extends from said gas supply part along a circumferential direction of said processing tube and the direction in which said substrates are stacked, and a gas flow regulating part disposed in a space inside said processing tube that is above a top-most gas supply opening and a top-most substrate and in a space inside said processing tube that is lower than a bottom-most substrate and a bottom-most gas supply opening.
